(19) United States
(12) Patent Application Publication
(10) Pub. No.: US 2025/0309854 A1
(43) Pub. Date: Oct. 2, 2025

(54) ELECTRONIC COMPONENT

(71) Applicant: TDK Corporation, Tokyo (JP)

(72) Inventors: Shuhei SAWAGUCHI, Tokyo (JP); Tetsuzo GOTO, Tokyo (JP); Yuta ASHIDA, Tokyo (JP); Masahiro TATEMATSU, Tokyo (JP); Keigo SHIBUYA, Tokyo (JP); Tomonori TERUI, Tokyo (JP)

(73) Assignee: TDK Corporation, Tokyo (JP)

(21) Appl. No.: 19/093,227

(22) Filed: Mar. 27, 2025

(30) Foreign Application Priority Data
Mar. 28, 2024 (JP) 2024-053617

(51) Int. Cl. H03H 7/01

(52) U.S. Cl. CPC H03H 7/0115; H03H 2210/015

(57) ABSTRACT

An electronic component includes an element body and a resonator within the element body. The resonator comprises two conductors extending in a second direction and an inductor conductor connecting them. When viewed from the second direction, at least one of the conductors has a first length in a first direction that is longer than a second length in a third direction. In a graph where the horizontal axis represents the second length of the conductor and the vertical axis represents the Q factor, if X1 and X2 are values on the horizontal axis and Y1 and Y2 are corresponding Q factors on the vertical axis, the slope (Y2−Y1)/(X2−X1) is negative.

### CROSS-REFERENCE TO RELATED APPLICATION

This application is based upon and claims the benefit of priority from Japanese Patent Application No. 2024-053617, filed on Mar. 28, 2024, the entire contents of which are incorporated herein by reference.

### TECHNICAL FIELD

The present disclosure relates to an electronic component.

### BACKGROUND

Japanese Unexamined Patent Publication No. 2002-57543 discloses an electronic component in which a plurality of inductors and a plurality of capacitors are formed in a stacked body formed by stacking insulator layers and a plurality of LC resonators electromagnetically coupled by the inductors and the capacitors are formed, and in which the inductor is formed by via holes joined in the stacking direction of the insulator layers, a coupling adjustment conductor formed by via holes joined in the stacking direction of the insulator layers is provided between at least two adjacent LC resonators of the plurality of LC resonators, and the coupling adjustment conductor is grounded.

### SUMMARY

An object of an aspect of the present disclosure is to provide an electronic component capable of improving the Q factor while achieving downsizing.

(1) An electronic component according to an aspect of the present disclosure includes: an element body formed by stacking a plurality of insulator layers; and a resonator placed in the element body; in the electronic component, the resonator includes two conductors extending in the stacking direction of the plurality of insulator layers and a connection conductor connecting the two conductors, in at least one conductor of the two conductors, when the conductor is viewed from the stacking direction, a first length in a direction orthogonal to the facing direction of the two conductors is longer than a second length in the facing direction, and in a graph in which the horizontal axis represents the value of the second length of the conductor and the vertical axis represents the Q factor, when a first value on the horizontal axis is denoted by X1, a second value on the horizontal axis is by X2, a first Q factor on the vertical axis at the first value X1 is by Y1, and a second Q factor on the vertical axis at the second value X2 is by Y2, the slope of the graph of (Y2−Y1)/(X2−X1) is negative.

In the electronic component according to an aspect of the present disclosure, in at least one conductor of the two conductors, when the conductor is viewed from the stacking direction, a first length in a direction orthogonal to the facing direction of the two conductors is longer than a second length in the facing direction. Thereby, in the electronic component, an opening formed by the two conductors and the connection conductor can be enlarged while an increase in the dimension of the element body in the facing direction is avoided. Therefore, in the electronic component, inductance can be increased while downsizing is achieved. In this configuration, in the electronic component, in a graph in which the horizontal axis represents the value of the second length of the conductor and the vertical axis represents the Q factor (quality factor), when a first Q factor on the vertical axis at a first value X1 is denoted by Y1 and a second Q factor on the vertical axis at a second value X2 is by Y2, the slope of the graph of (Y2−Y1)/(X2−X1) is negative. In the electronic component, the Q factor can be improved by having such characteristics.

(2) In the electronic component of (1) above, the second length of the conductor may be 125 μm or less. In this configuration, an opening formed by the two conductors and the connection conductor can be enlarged. Therefore, in the electronic component, inductance can be increased while downsizing is achieved.

(3) In the electronic component of (1) or (2) above, a plurality of recesses may be provided on the side surface of the conductor, and the plurality of recesses may be arranged facing in the facing direction and extend in the stacking direction. In this configuration, the bonding strength between the element body and the conductor can be improved.

(4) In the electronic component of any one of (1) to (3) above, for each of the two conductors, the first length may be longer than the second length, and each of the first length and the second length may be the same between the two conductors. In this configuration, the cross-sectional areas of the two conductors can be increased, and therefore the resistance values of the two conductors can be reduced. Therefore, in the electronic component, the Q factor can be still further improved.

(5) In the electronic component of any one of (1) to (4) above, as viewed from the stacking direction, a direction orthogonal to the facing direction of the two conductors may be along the longitudinal direction of the element body. In this configuration, the resonator can be efficiently placed in the element body of the conductor.

(6) In the electronic component of any one of (1) to (5) above, the resonator may include a plurality of sets each consisting of two conductors and a connection conductor.

(7) An electronic component according to an aspect of the present disclosure includes: an element body formed by stacking a plurality of insulator layers; and a resonator placed in the element body; in the electronic component, the resonator includes two conductors extending in the stacking direction of the plurality of insulator layers and a connection conductor connecting the two conductors, in at least one conductor of the two conductors, when the conductor is viewed from the stacking direction, a first length in a direction orthogonal to the facing direction of the two conductors is longer than a second length in the facing direction, and in a graph in which the horizontal axis represents the width dimension in the facing direction of the two conductors and the vertical axis represents the Q factor, when a first value on the horizontal axis is denoted by X1, a second value on the horizontal axis is by X2, a first Q factor on the vertical axis at the first value X1 is by Y1, and a second Q factor on the vertical axis at the second value X2 is by Y2, the value of (Y2−Y1)/(X2−X1) is negative.

In the electronic component according to an aspect of the present disclosure, in at least one conductor of the two conductors, when the conductor is viewed from the stacking direction, a first length in a direction orthogonal to the facing direction of the two conductors is longer than a second length in the facing direction. Thereby, in the electronic component, an opening formed by the two conductors and the connection conductor can be enlarged while an increase in the dimension of the element body in the facing direction is avoided. Therefore, in the electronic component, inductance can be increased while downsizing is achieved. In this configuration, in the electronic component, in a graph in which the horizontal axis represents the value of the width dimension in the facing direction of the two conductors and the vertical axis represents the Q factor (quality factor), when a first Q factor on the vertical axis at a first value X1 is denoted by Y1 and a second Q factor on the vertical axis at a second value X2 is by Y2, the slope of the graph of (Y2−Y1)/(X2−X1) is negative. In the electronic component, the Q factor can be improved by having such characteristics.

According to an aspect of the present disclosure, the Q factor can be improved while downsizing is achieved.

### BRIEF DESCRIPTION OF THE DRAWINGS

FIG. 1 is a perspective view of an electronic component according to a first embodiment;

FIG. 2 is an exploded perspective view of the electronic component;

FIG. 3 is a diagram showing a cross-sectional configuration of a conductor;

FIG. 4 is a diagram showing a resonator;

FIG. 5 is a graph showing a relationship between a second length of the conductor and the Q factor;

FIG. 6 is a perspective view of an electronic component according to a second embodiment;

FIG. 7 is a diagram showing a cross-sectional configuration of a conductor;

FIG. 8 is a graph showing a relationship between a second length of the conductor and the Q factor;

FIG. 9 is a perspective view of an electronic component according to a third embodiment;

FIG. 10 is a diagram showing a cross-sectional configuration of a conductor; and

FIG. 11 is a graph showing a relationship between a second length of the conductor and the Q factor.

### DETAILED DESCRIPTION

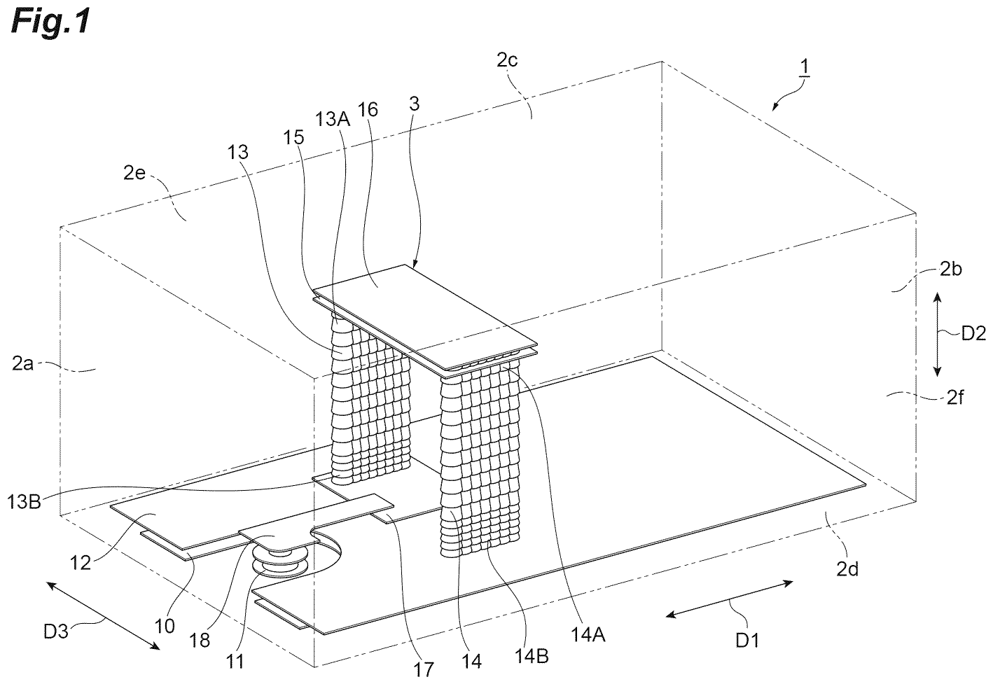

Hereinbelow, preferred embodiments of the present invention are described in detail with reference to the accompanying drawings. In the description of the drawings, the same or equivalent elements are denoted by the same reference signs, and a repeated description is omitted.

[First Embodiment] FIG. 1 is a perspective view of an electronic component according to a first embodiment. As shown in FIG. 1, an electronic component 1 includes an element body 2 and a resonator 3. In FIG. 1, the element body 2 is indicated by an alternate long and two short dashes line.

The element body 2 exhibits a rectangular parallelepiped shape. The rectangular parallelepiped shape includes a rectangular parallelepiped shape in which corner portions and ridge line portions are chamfered, and a rectangular parallelepiped shape in which corner portions and ridge line portions are rounded. The element body 2 has, as outer surfaces, a pair of end surfaces 2a and 2b, a pair of main surfaces 2c and 2d, and a pair of side surfaces 2e and 2f. The end surfaces 2a and 2b face each other. The main surfaces 2c and 2d face each other. The side surfaces 2e and 2f face each other. In the following, the facing direction of the end surfaces 2a and 2b is defined as a first direction D1, the facing direction of the main surfaces 2c and 2d is defined as a second direction D2, and the facing direction of the side surfaces 2e and 2f is defined to as a third direction D3. The first direction D1, the second direction D2, and the third direction D3 are substantially orthogonal to each other.

The end surfaces 2a and 2b extend in the second direction D2 to link the main surfaces 2c and 2d. The end surfaces 2a and 2b extend also in the third direction D3 to link the side surfaces 2e and 2f. The main surfaces 2c and 2d extend in the first direction D1 to link the end surfaces 2a and 2b. The main surfaces 2c and 2d extend also in the third direction D3 to link the side surfaces 2e and 2f. The side surfaces 2e and 2f extend in the first direction D1 to link the end surfaces 2a and 2b. The side surfaces 2e and 2f extend also in the second direction D2 to link the main surfaces 2c and 2d.

The main surface 2d is a mounting surface; for example, when the electronic component 1 is mounted on another electronic device (for example, a circuit base material or a multilayer electronic component) (not illustrated), the main surface 2d is a surface facing the other electronic device. The end surfaces 2a and 2b are surfaces continuing from the mounting surface (that is, the main surface 2d).

The length in the first direction D1 of the element body 2 is longer than the length in the second direction D2 of the element body 2 and the length in the third direction D3 of the element body 2. The first direction D1 is the longitudinal direction of the element body 2. The length in the second direction D2 of the element body 2 is shorter than the length in the third direction D3 of the element body 2. That is, in the present embodiment, each of the end surfaces 2a and 2b, the main surfaces 2c and 2d, and the side surfaces 2e and 2f exhibits a rectangle shape. The length in the second direction D2 of the element body 2 may be substantially equal to the length in the third direction D3 of the element body 2, or may be longer than the length in the third direction D3 of the element body 2.

In the present embodiment, “substantially equal” may mean not only “equal” but also a value including a minute difference, a manufacturing error, or the like in a preset range. For example, it is specified that, when each of a plurality of values is included in the range of ±5% of the average value of the plurality of values, the plurality of values are substantially equal.

The element body 2 is formed by a plurality of element body layers (insulator layers) 6 being stacked in the second direction D2. That is, the stacking direction of the element body 2 is the second direction D2. In the actual element body 2, the plurality of element body layers 6 may be integrated to such a degree that the boundaries between layers cannot be visually recognized, or may be integrated such that the boundaries between layers can be visually recognized.

The element body layer is formed of, for example, a sintered body of a ceramic green sheet containing a dielectric material. The dielectric material includes, for example, at least one selected from a BaTiO₃-based material, a Ba(Ti,Zr)O₃-based material, a (Ba,Ca)TiO₃-based material, a glass material, and an alumina material.

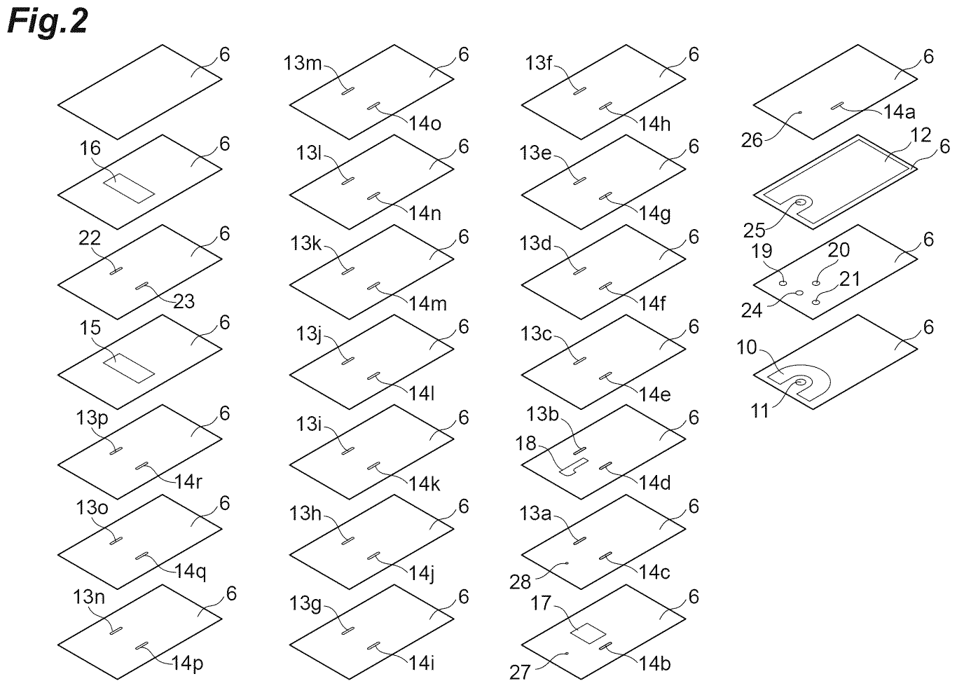

FIG. 2 is an exploded perspective view of the electronic component 1. As shown in FIGS. 1 and 2, the resonator 3 includes a first terminal conductor 10, a second terminal conductor 11, a ground conductor 12, a first conductor 13, a second conductor 14, an inductor conductor (connection conductor) 15, an inductor conductor (connection conductor) 16, a capacitor conductor 17, and a capacitor conductor 18.

The first terminal conductor 10 is placed on the main surface 2d side of the element body 2. The first terminal conductor 10 is a portion to be connected to an electronic device or the like. The first terminal conductor 10 exhibits a U-shaped form as viewed from the second direction D2. The first terminal conductor 10 is formed of, for example, a conductive material (for example, Cu). The first terminal conductor 10 may be provided with a plating layer (not illustrated) containing, for example, Ni, Sn, Au, or the like by electrolytic plating or electroless plating. The plating layer may include, for example, a Ni plating film containing Ni and covering the first terminal conductor 10, and a Au plating film containing Au and covering the Ni plating film.

The second terminal conductor 11 is placed on the main surface 2d side of the element body 2. The second terminal conductor 11 is a portion to be connected to an electronic device or the like. The second terminal conductor 11 exhibits a circular shape as viewed from the second direction D2. The second terminal conductor 11 is formed of, for example, a conductive material (for example, Cu). The second terminal conductor 11 may be provided with a plating layer (not illustrated) containing, for example, Ni, Sn, Au, or the like by electrolytic plating or electroless plating.

The ground conductor 12 is placed on the main surface 2d side of the element body 2. The ground conductor 12 exhibits a substantially rectangular shape as viewed from the second direction D2. The ground conductor 12 is electrically connected to the first terminal conductor 10. The ground conductor 12 and the first terminal conductor 10 are electrically connected by a connection conductor 19, a connection conductor 20, and a connection conductor 21.

The first conductor 13 extends along the second direction D2. The first conductor 13 can be composed of a plurality of conductor portions 13a, 13b, 13c, 13d, 13e, 13f, 13g, 13h, 13i, 13j, 13k, 13l, 13m, 13n, 13o, and 13p. The first conductor 13 is placed in a position nearer to the side surface 2e of the element body 2. The first conductor 13 has a first end portion 13A and a second end portion 13B. The first end portion 13A of the first conductor 13 is connected to the inductor conductor 15. The second end portion 13B of the first conductor 13 is connected to the capacitor conductor 17.

The second conductor 14 extends along the second direction D2. The second conductor 14 can be composed of a plurality of conductor portions 14a, 14b, 14c, 14d, 14e, 14f, 14g, 14h, 14i, 14j, 14k, 14l, 14m, 14n, 14o, 14p, 14q, and 14r. The second conductor 14 is placed in a position nearer to the side surface 2f of the element body 2. The second conductor 14 is placed in a position facing the first conductor 13 in the third direction D3. The first conductor 13 and the second conductor 14 are arranged apart from each other in the third direction D3. The second conductor 14 has a first end portion 14A and a second end portion 14B. The first end portion 14A of the second conductor 14 is connected to the inductor conductor 15. The second end portion 14B of the second conductor 14 is connected to the ground conductor 12.

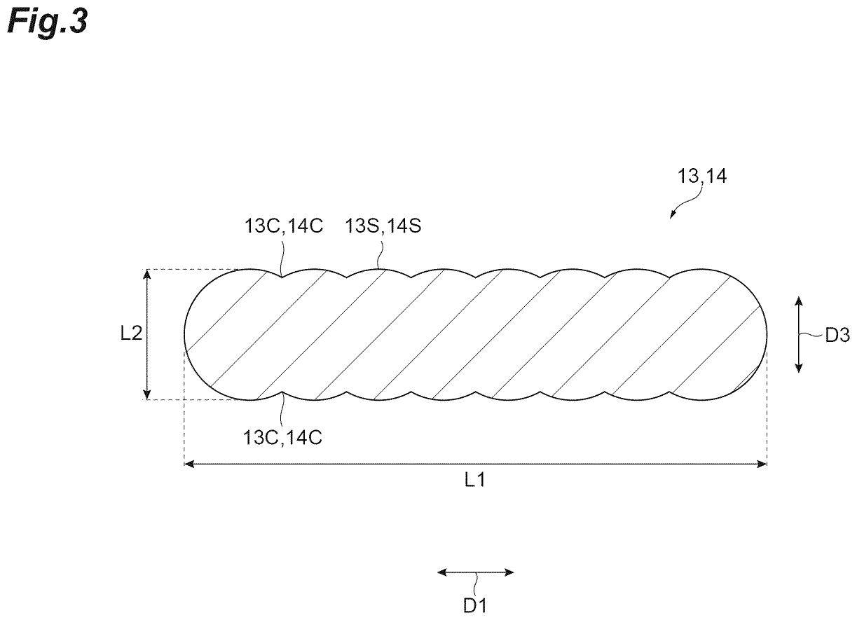

FIG. 3 is a diagram showing a cross-sectional configuration of the conductor (the first conductor 13 and the second conductor 14). The cross section of each of the first conductor 13 and the second conductor 14 shown in FIG. 3 is a cross section in a plane along the first direction D1 and the third direction D3. As shown in FIG. 3, the first conductor 13 and the second conductor 14 exhibit the same shape, and have the same dimensions. For the first conductor 13 and the second conductor 14, a first length L1 in the first direction D1 is longer than a second length L2 in the third direction D3 (L1>L2) when viewed from the second direction D2. In the present embodiment, each of the first length L1 and the second length L2 is the same between the first conductor 13 and the second conductor 14. In the present embodiment, the second length L2 is, for example, 125 μm or less, preferably 100 μm or less. The second length L2 can be, for example, 20 μm or more.

The first conductor 13 and the second conductor 14 are arranged such that the first length L1 is along the first direction D1 and the second length L2 is along the third direction D3. That is, the extending directions of the first conductor 13 and the second conductor 14 are orthogonal to the direction (the third direction D3) in which the first conductor 13 and the second conductor 14 stand side by side. “Orthogonal” includes substantially orthogonal, and can include, for example, a range of about ±3°.

In the present embodiment, each of the first conductor 13 and the second conductor 14 exhibits a shape in which a plurality of (in the example shown in FIG. 3, eight) circles overlap. Specifically, each of the first conductor 13 and the second conductor 14 exhibits a shape in which parts of a pair of adjacent circles overlap. For example, two adjacent circles overlap such that the outer periphery of one circle passes through the center of the other circle. Each of the side surfaces 13S and 14S of the first conductor 13 and the second conductor 14 is formed in a curved surface. Pluralities of recesses 13C and 14C are provided on the side surfaces 13S and 14S of the first conductor 13 and the second conductor 14. The recesses 13C and 14C extend in the second direction D2. The recesses 13C and 14C are arranged at a predetermined interval in the first direction D1. The recesses 13C and 14C are arranged in facing positions in the third direction D3.

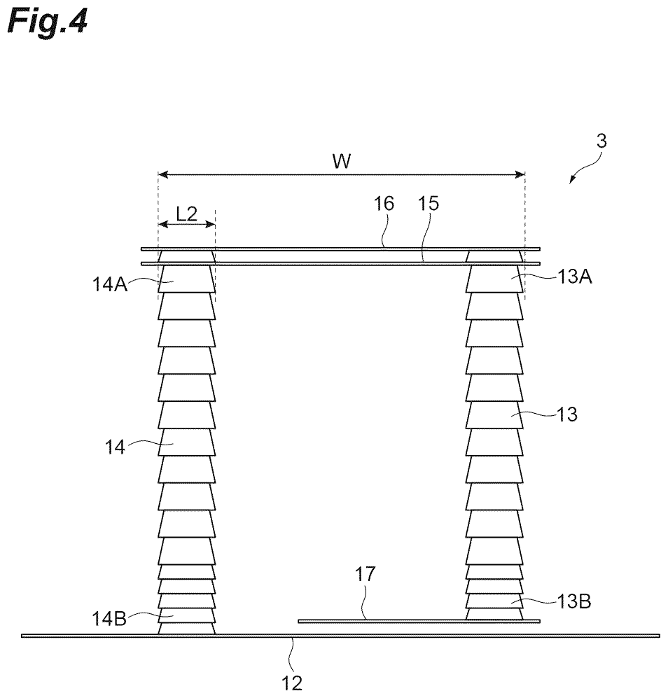

FIG. 4 is a diagram showing the resonator 3. As shown in FIG. 4, the first conductor 13 and the second conductor 14 are arranged to have a width (width dimension) W in the third direction D3. The width W is, for example, 600 μm. The width W is the distance between the end on the side surface 2e side of the first conductor 13 and the end on the side surface 2f side of the second conductor 14. That is, the width W is the maximum distance between the first conductor 13 and the second conductor 14 in the third direction D3.

The inductor conductor 15 forms a part of an inductor. In the present embodiment, as shown in FIGS. 1 and 2, the inductor conductor 15 exhibits a rectangular shape. The inductor conductor 15 extends in a straight line along the third direction D3. The inductor conductor 15 is stretched over the first end portion 13A of the first conductor 13 and the first end portion 14A of the second conductor 14. The inductor conductor 15 electrically connects the first conductor 13 and the second conductor 14.

The inductor conductor 16 forms a part of the inductor. In the present embodiment, the inductor conductor 16 exhibits a rectangular shape. That is, the inductor conductor 16 exhibits the same shape as the inductor conductor 15. The inductor conductor 16 extends in a straight line along the third direction D3. The inductor conductor 16 is electrically connected to the inductor conductor 15 by a connection conductor 22 and a connection conductor 23. The inductor conductor 16 is placed facing the inductor conductor 15 in the second direction D2. The inductor conductor 16 electrically connects the first conductor 13 and the second conductor 14.

The capacitor conductor 17 exhibits a rectangular shape as viewed from the second direction D2. The capacitor conductor 17 forms a capacitor together with the ground conductor 12. The capacitor conductor 17 is connected to the second end portion 13B of the first conductor 13. The capacitor conductor 17 is placed with a predetermined gap in the second direction D2 from the ground conductor 12.

The capacitor conductor 18 is electrically connected to the second terminal conductor 11. The capacitor conductor 18 and the second terminal conductor 11 are electrically connected by a connection conductor 24, a connection conductor 25, a connection conductor 26, a connection conductor 27, and a connection conductor 28. The capacitor conductor 18 is placed with a predetermined gap in the second direction D2 from the capacitor conductor 17.

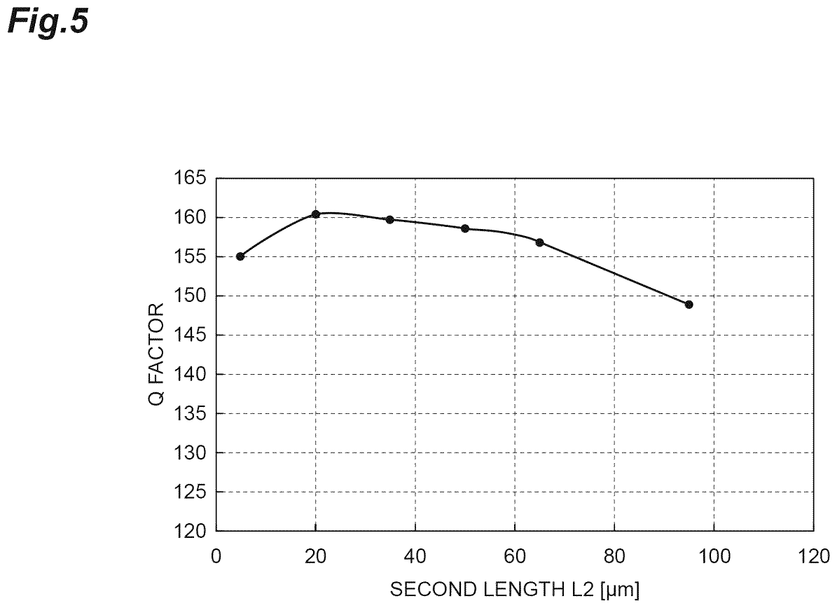

FIG. 5 is a graph showing a relationship between the second length L2 of each of the first conductor 13 and the second conductor 14 and the Q factor. In FIG. 5, the horizontal axis represents the second length L2 [μm] of each of the first conductor 13 and the second conductor 14, and the vertical axis represents the Q factor. FIG. 5 shows a result at a frequency of 9 GHz.

As shown in FIG. 5, in the electronic component 1, when a first value on the horizontal axis is denoted by X1, a second value on the horizontal axis is by X2, a first Q factor on the vertical axis at the first value X1 is by Y1, and a second Q factor on the vertical axis at the second value X2 is by Y2,
the slope of the graph of

(Y2−Y1)/(X2−X1)
is negative. That is, in the electronic component 1, the first conductor 13 and the second conductor 14 are configured such that the slope of the graph is negative in the above relationship.

In the example shown in FIG. 5, in the electronic component 1, for example, X1 can be 20 μm, X2 can be 35 μm, Y1 can be 160.4, and Y2 can be 159.7. In this case, the slope of the graph is negative. In the electronic component 1, for example, X1 can be 35 μm, X2 can be 50 μm, Y1 can be 159.7, and Y2 can be 158.6. In the electronic component 1, for example, X1 can be 50 μm, X2 can be 65 μm, Y1 can be 158.6, and Y2 can be 156.9. In the electronic component 1, for example, X1 can be 65 μm, X2 can be 95 μm, Y1 can be 156.9, and Y2 can be 149.0. In the present embodiment, the Q factor is maximized when the second length L2 is 20 μm.

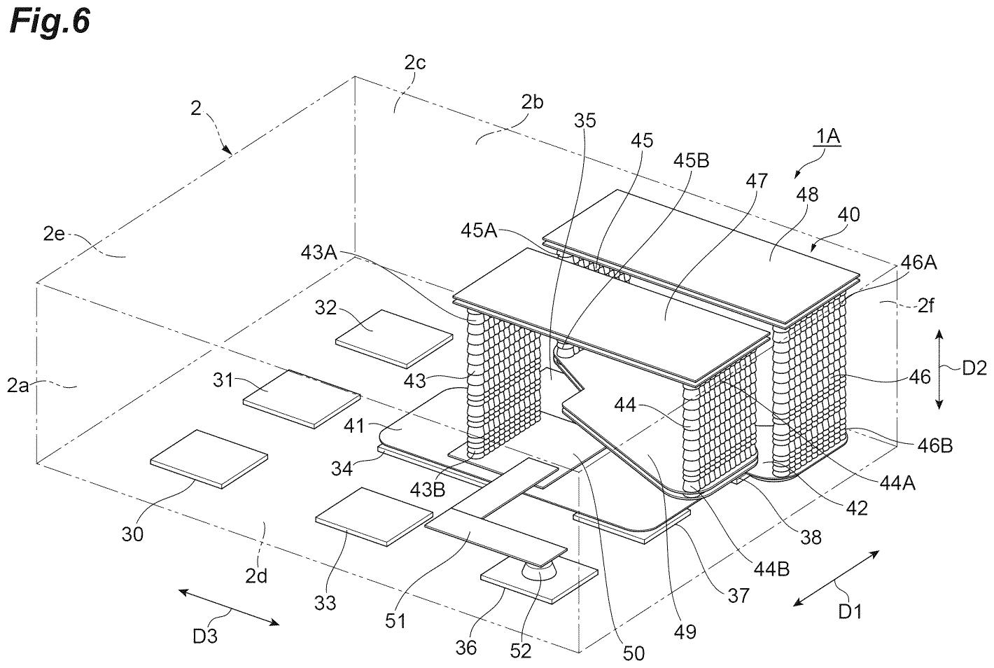

As described hereinabove, in the electronic component 1 according to the present embodiment, for the first conductor 13 and the second conductor 14, the first length L1 in the first direction D1 is longer than the second length L2 in the third direction D3 (L1>L2) when viewed from the second direction D2. Thereby, in the electronic component 1, an opening formed by the first conductor 13, the second conductor 14, and the inductor conductor 15 can be enlarged while an increase in the dimension of the element body 2 in the third direction D3 is avoided. Therefore, in the electronic component 1, inductance can be increased while downsizing is achieved. In this configuration, in the electronic component 1, in a graph in which the horizontal axis represents the value of the second length L2 of each of the first conductor 13 and the second conductor 14 and the vertical axis represents the Q factor (quality factor), when a first Q factor on the vertical axis at a first value X1 is denoted by Y1 and a second Q factor on the vertical axis at a second value X2 is by Y2, the slope of the graph of (Y2−Y1)/(X2−X1) is negative. In the electronic component 1, the Q factor can be improved by having such characteristics.

[Second Embodiment] Next, a second embodiment is described. FIG. 6 is a perspective view showing an electronic component according to the second embodiment. As shown in FIG. 6, an electronic component 1A includes an element body 2, terminal electrodes 30, 31, 32, 33, 34, 35, 36, 37, and 38, and a resonator 40.

Each of the terminal electrodes 30 to 38 is provided on the element body 2. Each of the terminal electrodes 30 to 38 is placed on a main surface 2d of the element body 2. Each of the terminal electrodes 30 to 38 exhibits a rectangle shape (rectangular shape).

The resonator 40 includes a first ground conductor 41, a second ground conductor 42, a first conductor 43, a second conductor 44, a third conductor 45, a fourth conductor 46, a first inductor conductor (connection conductor) 47, a second inductor conductor (connection conductor) 48, a connection conductor 49, a capacitor conductor 50, and a capacitor conductor 51.

The first ground conductor 41 is placed on the main surface 2d side of the element body 2. The first ground conductor 41 exhibits a substantially rectangular shape as viewed from the second direction D2. The first ground conductor 41 is electrically connected to the terminal electrode 34.

The second ground conductor 42 is placed on the main surface 2d side of the element body 2. The second ground conductor 42 is electrically connected to the terminal electrode 38.

The first conductor 43 extends along the second direction D2. The first conductor 43 can be composed of a plurality of conductor portions. The first conductor 43 has a first end portion 43A and a second end portion 43B. The first end portion 43A of the first conductor 43 is connected to the first inductor conductor 47. The second end portion 43B of the first conductor 43 is connected to the capacitor conductor 50.

The second conductor 44 extends along the second direction D2. The second conductor 44 can be composed of a plurality of conductor portions. The second conductor 44 is placed in a position facing the first conductor 43 in the third direction D3. The first conductor 43 and the second conductor 44 are arranged apart from each other in the third direction D3. The second conductor 44 has a first end portion 44A and a second end portion 44B. The first end portion 44A of the second conductor 44 is connected to the first inductor conductor 47. The second end portion 44B of the second conductor 44 is connected to the connection conductor 49.

The third conductor 45 extends along the second direction D2. The third conductor 45 can be composed of a plurality of conductor portions. The third conductor 45 has a first end portion 45A and a second end portion 45B. The first end portion 45A of the third conductor 45 is connected to the second inductor conductor 48. The second end portion 45B of the third conductor 45 is connected to the connection conductor 49.

The fourth conductor 46 extends along the second direction D2. The fourth conductor 46 can be composed of a plurality of conductor portions. The fourth conductor 46 is placed in a position facing the third conductor 45 in the third direction D3. The fourth conductor 46 and the third conductor 45 are arranged apart from each other in the third direction D3. The fourth conductor 46 has a first end portion 46A and a second end portion 46B. The first end portion 46A of the fourth conductor 46 is connected to the second inductor conductor 48. The second end portion 46B of the fourth conductor 46 is connected to the second ground conductor 42.

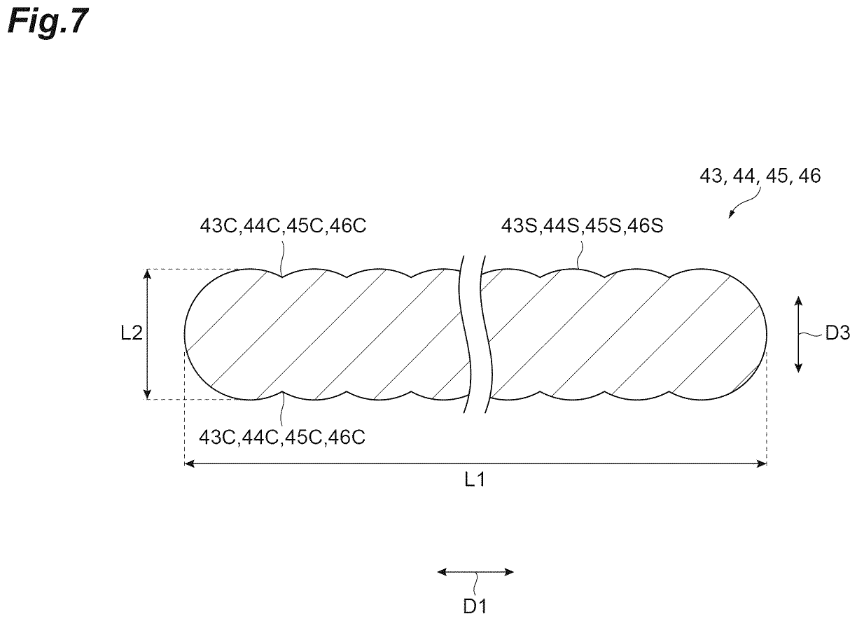

FIG. 7 is a diagram showing a cross-sectional configuration of the conductor (the first conductor 43, the second conductor 44, the third conductor 45, and the fourth conductor 46). The cross section of each of the first conductor 43, the second conductor 44, the third conductor 45, and the fourth conductor 46 shown in FIG. 7 is a cross section in a plane along the first direction D1 and the third direction D3. As shown in FIG. 7, for the first conductor 43, the second conductor 44, the third conductor 45, and the fourth conductor 46, a first length L1 in the third direction D3 is longer than a second length L2 in the first direction D1 (L1>L2) when viewed from the second direction D2. In the present embodiment, the second length L2 is, for example, 160 μm or less, preferably 100 μm or less. The second length L2 can be, for example, 35 μm or more.

The first conductor 43, the second conductor 44, the third conductor 45, and the fourth conductor 46 are arranged such that the first length L1 is along the first direction D1 and the second length L2 is along the third direction D3. That is, the extending directions of the first conductor 43, the second conductor 44, the third conductor 45, and the fourth conductor 46 are orthogonal to the direction (the third direction D3) in which the first conductor 43 and the second conductor 44 stand side by side and the third conductor 45 and the fourth conductor 46 stand side by side. “Orthogonal” includes substantially orthogonal, and can include, for example, a range of about ±3°.

In the present embodiment, each of the first conductor 43, the second conductor 44, the third conductor 45, and the fourth conductor 46 exhibits a shape in which a plurality of circles overlap. Specifically, each of the first conductor 43, the second conductor 44, the third conductor 45, and the fourth conductor 46 exhibits a shape in which parts of a pair of adjacent circles overlap. For example, two adjacent circles overlap such that the outer periphery of one circle passes through the center of the other circle. Each of the side surfaces 43S, 44S, 45S, and 46S of the first conductor 43, the second conductor 44, the third conductor 45, and the fourth conductor 46 is formed in a curved surface. Pluralities of recesses 43C, 44C, 45C, and 46C are provided on the side surfaces 43S, 44S, 45S, and 46S of the first conductor 43, the second conductor 44, the third conductor 45, and the fourth conductor 46. The recesses 43C, 44C, 45C, and 46C extend in the second direction D2. The recesses 43C, 44C, 45C, and 46C are arranged at a predetermined interval in the first direction D1. The recesses 43C, 44C, 45C, and 46C are arranged in facing positions in the third direction D3.

The first inductor conductor 47 forms a part of an inductor. In the present embodiment, as shown in FIG. 6, the first inductor conductor 47 exhibits a rectangular shape. The first inductor conductor 47 extends along the third direction D3. The first inductor conductor 47 may be composed of two members. The first inductor conductor 47 is stretched over the first end portion 43A of the first conductor 43 and the first end portion 44A of the second conductor 44. The first inductor conductor 47 electrically connects the first conductor 43 and the second conductor 44.

The second inductor conductor 48 forms a part of the inductor. In the present embodiment, the second inductor conductor 48 exhibits a rectangular shape. That is, the second inductor conductor 48 exhibits the same shape as the first inductor conductor 47. The second inductor conductor 48 extends along the third direction D3. The second inductor conductor 48 may be composed of two members. The second inductor conductor 48 is stretched over the first end portion 45A of the third conductor 45 and the first end portion 46A of the fourth conductor 46. The second inductor conductor 48 electrically connects the third conductor 45 and the fourth conductor 46.

The connection conductor 49 forms a part of the inductor. The connection conductor 49 is connected to the second end portion 44B of the second conductor 44 and the second end portion 45B of the third conductor 45. The connection conductor 49 electrically connects the second conductor 44 and the third conductor 45.

The capacitor conductor 50 exhibits a rectangular shape as viewed from the second direction D2. The capacitor conductor 50 forms a capacitor together with the first ground conductor 41. The capacitor conductor 50 is connected to the second end portion 43B of the first conductor 43. The capacitor conductor 50 is placed with a predetermined gap in the second direction D2 from the first ground conductor 41.

The capacitor conductor 51 exhibits an L-shaped form as viewed from the second direction D2. The capacitor conductor 51 is electrically connected to the terminal electrode 36. The capacitor conductor 51 and the terminal electrode 36 are electrically connected by a connection conductor 52. The capacitor conductor 51 is placed with a predetermined gap in the second direction D2 from the capacitor conductor 50.

In the resonator 40, the first conductor 43, the second conductor 44, and the first inductor conductor 47 constitute an inductor, and the third conductor 45, the fourth conductor 46, and the second inductor conductor 48 constitute an inductor. The resonator 40 has two sets (each consisting of conductors and an inductor conductor) constituting inductors.

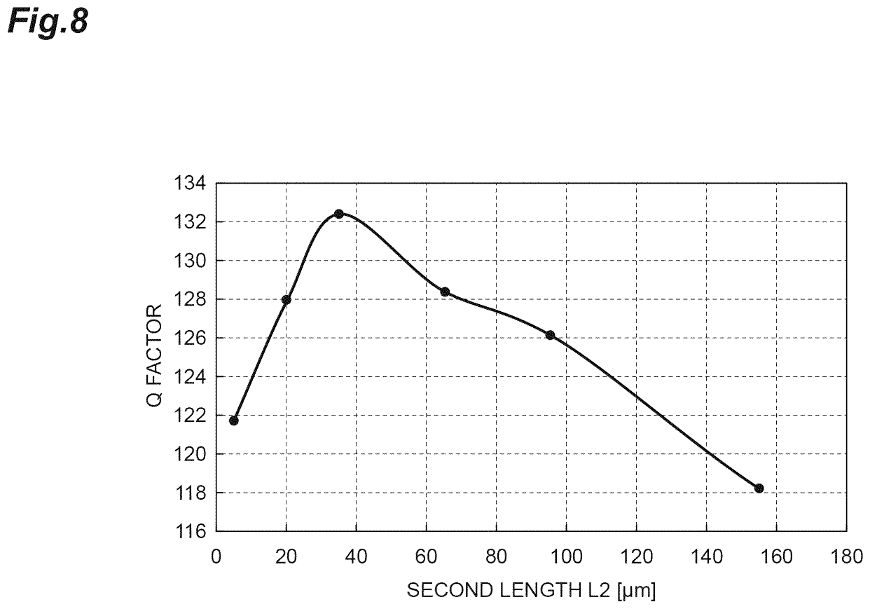

FIG. 8 is a graph showing a relationship between the second length L2 of each of the first conductor 43, the second conductor 44, the third conductor 45, and the fourth conductor 46 and the Q factor. In FIG. 8, the horizontal axis represents the second length L2 [μm] of each of the first conductor 43, the second conductor 44, the third conductor 45, and the fourth conductor 46, and the vertical axis represents the Q factor. FIG. 8 shows a result at a frequency of 3.5 GHz.

As shown in FIG. 8, in the electronic component 1A, when a first value on the horizontal axis is denoted by X1, a second value on the horizontal axis is by X2, a first Q factor on the vertical axis at the first value X1 is by Y1, and a second Q factor on the vertical axis at the second value X2 is by Y2,
the slope of the graph of

(Y2−Y1)/(X2−X1)
is negative. That is, in the electronic component 1A, the first conductor 43, the second conductor 44, the third conductor 45, and the fourth conductor 46 are configured such that the slope of the graph is negative in the above relationship.

In the example shown in FIG. 8, in the electronic component 1A, for example, X1 can be 35 μm, X2 can be 65 μm, Y1 can be 132.3, and Y2 can be 128.3. In this case, the slope of the graph is negative. In the electronic component 1A, for example, X1 can be 65 μm, X2 can be 95 μm, Y1 can be 128.3, and Y2 can be 126.1. In the electronic component 1A, for example, X1 can be 95 μm, X2 can be 155 μm, Y1 can be 126.1, and Y2 can be 118.2. In the present embodiment, the Q factor is maximized when the second length L2 is 35 μm.

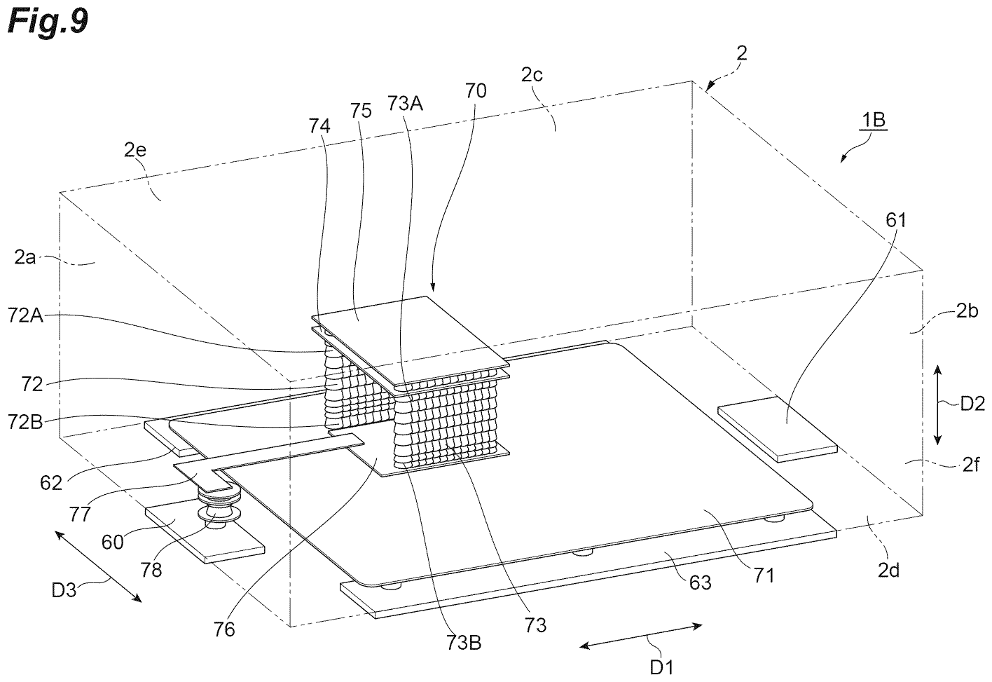

As described hereinabove, in the electronic component 1A according to the present embodiment, for the first conductor 43, the second conductor 44, the third conductor 45, and the fourth conductor 46, the first length L1 in the third direction D3 is longer than the second length L2 in the first direction D1 (L1>L2) when viewed from the second direction D2. Thereby, in the electronic component 1A, an opening formed by the first conductor 43, the second conductor 44, and the first inductor conductor 47 and an opening formed by the third conductor 45, the fourth conductor 46, and the second inductor conductor 48 can be enlarged while an increase in the dimension of the element body 2 in the first direction D1 is avoided. Therefore, in the electronic component 1A, inductance can be increased while downsizing is achieved. In this configuration, in the electronic component 1A, in a graph in which the horizontal axis represents the value of the second length L2 of each of the first conductor 43, the second conductor 44, the third conductor 45, and the fourth conductor 46 and the vertical axis represents the Q factor (quality factor), when a first Q factor on the vertical axis at a first value X1 is denoted by Y1 and a second Q factor on the vertical axis at a second value X2 is by Y2, the slope of the graph of (Y2−Y1)/(X2−X1) is negative. In the electronic component 1A, the Q factor can be improved by having such characteristics.

[Third Embodiment] Next, a third embodiment is described. FIG. 9 is a perspective view showing an electronic component according to a third embodiment. As shown in FIG. 9, an electronic component 1B includes an element body 2, terminal electrodes 60, 61, 62, and 63, and a resonator 70.

Each of the terminal electrodes 60 to 63 is provided on the element body 2. Each of the terminal electrodes 60 to 63 is placed on a main surface 2d of the element body 2. Each of the terminal electrodes 60 to 63 exhibits a rectangle shape (rectangular shape). The terminal electrode 60 is placed in a position nearer to an end surface 2a. The terminal electrode 61 is placed in a position nearer to an end surface 2b. The terminal electrode 62 is placed in a position nearer to a side surface 2e. The terminal electrode 63 is placed in a position nearer to a side surface 2f. The terminal electrode 62 and the terminal electrode 63 extend along the first direction D1.

The resonator 70 includes a ground conductor 71, a first conductor 72, a second conductor 73, an inductor conductor (connection conductor) 74, an inductor conductor (connection conductor) 75, a capacitor conductor 76, and a capacitor conductor 77.

The ground conductor 71 is placed on the main surface 2d side of the element body 2. The ground conductor 71 exhibits a substantially rectangular shaped as viewed from the second direction D2. The ground conductor 71 is electrically connected to the terminal electrode 62 and the terminal electrode 63.

The first conductor 72 extends along the second direction D2. The first conductor 72 can be composed of a plurality of conductor portions. The first conductor 72 has a first end portion 72A and a second end portion 72B. The first end portion 72A of the first conductor 72 is connected to the inductor conductor 74. The second end portion 72B of the first conductor 72 is connected to the ground conductor 71.

The second conductor 73 extends along the second direction D2. The second conductor 73 can be composed of a plurality of conductor portions. The second conductor 73 is placed in a position facing the first conductor 72 in the third direction D3. The first conductor 72 and the second conductor 73 are arranged apart from each other in the third direction D3. The second conductor 73 has a first end portion 73A and a second end portion 73B. The first end portion 73A of the second conductor 73 is connected to the inductor conductor 74. The second end portion 73B of the second conductor 73 is connected to the capacitor conductor 76.

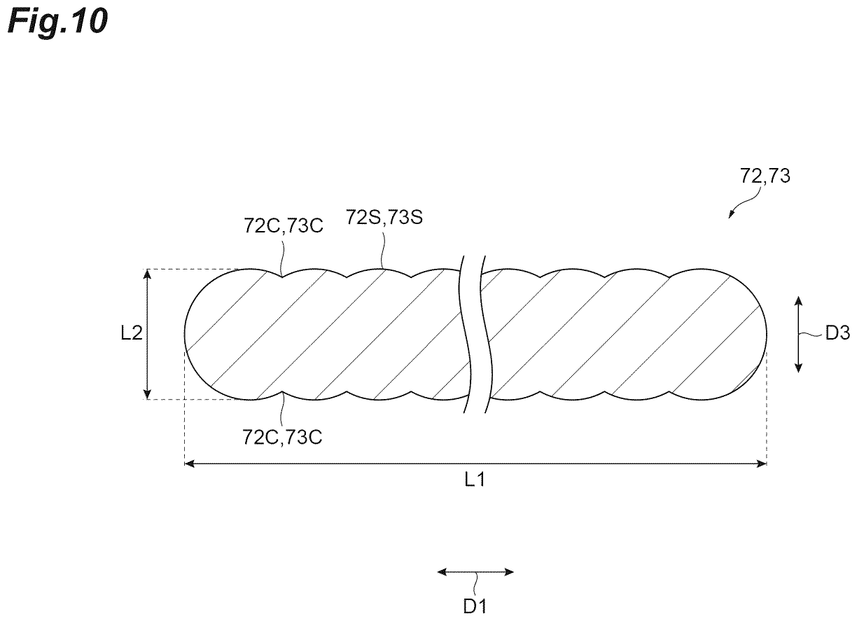

FIG. 10 is a diagram showing a cross-sectional configuration of the conductor (the first conductor 72 and the second conductor 73). The cross section of each of the first conductor 72 and the second conductor 73 shown in FIG. 10 is a cross section in a plane along the first direction D1 and the third direction D3. As shown in FIG. 10, for the first conductor 72 and the second conductor 73, a first length L1 in the first direction D1 is longer than a second length L2 in the third direction D3 (L1>L2) when viewed from the second direction D2. In the present embodiment, the second length L2 is, for example, 125 μm or less, preferably 95 μm or less. The second length L2 can be, for example, 35 μm or more.

The first conductor 72 and the second conductor 73 are arranged such that the first length L1 is along the first direction D1 and the second length L2 is along the third direction D3. That is, the extending directions of the first conductor 72 and the second conductor 73 are orthogonal to the direction (the third direction D3) in which the first conductor 72 and the second conductor 73 stand side by side. “Orthogonal” includes substantially orthogonal, and can include, for example, a range of about ±3°.

In the present embodiment, each of the first conductor 72 and the second conductor 73 exhibits a shape in which a plurality of circles overlap. Specifically, each of the first conductor 72 and the second conductor 73 exhibits a shape in which parts of a pair of adjacent circles overlap. For example, two adjacent circles overlap such that the outer periphery of one circle passes through the center of the other circle. Each of the side surfaces 72S and 73S of the first conductor 72 and the second conductor 73 is formed in a curved surface. Pluralities of recesses 72C and 73C are provided on the side surfaces 72S and 73S of the first conductor 72 and the second conductor 73. The recesses 72C and 73C extend in the second direction D2. The recesses 72C and 73C are arranged at a predetermined interval in the first direction D1. The recesses 72C and 73C are arranged in facing positions in the third direction D3.

The inductor conductor 74 forms a part of an inductor. In the present embodiment, as shown in FIG. 9, the inductor conductor 74 exhibits a rectangular shape. The inductor conductor 74 extends along the third direction D3. The inductor conductor 74 is stretched over the first end portion 72A of the first conductor 72 and the first end portion 73A of the second conductor 73. The inductor conductor 74 electrically connects the first conductor 72 and the second conductor 73.

The inductor conductor 75 forms a part of the inductor. In the present embodiment, the inductor conductor 75 exhibits a rectangular shape. That is, the inductor conductor 75 exhibits the same shape as the inductor conductor 74. The inductor conductor 75 extends along the third direction D3. The inductor conductor 75 is electrically connected to the inductor conductor 74 by a connection conductor. The inductor conductor 75 is placed facing the inductor conductor 74 in the second direction D2. The inductor conductor 75 electrically connects the first conductor 72 and the second conductor 73.

The capacitor conductor 76 exhibits a rectangular shape as viewed from the second direction D2. The capacitor conductor 76 forms a capacitor together with the ground conductor 71. The capacitor conductor 76 is connected to the second end portion 73B of the second conductor 73. The capacitor conductor 76 is placed with a predetermined gap in the second direction D2 from the ground conductor 71.

The capacitor conductor 77 exhibits an L-shaped form as viewed from the second direction D2. The capacitor conductor 77 is electrically connected to the terminal electrode 60. The capacitor conductor 77 and the terminal electrode 60 are electrically connected by a connection conductor 78. The capacitor conductor 77 is placed with a predetermined gap in the second direction D2 from the capacitor conductor 76.

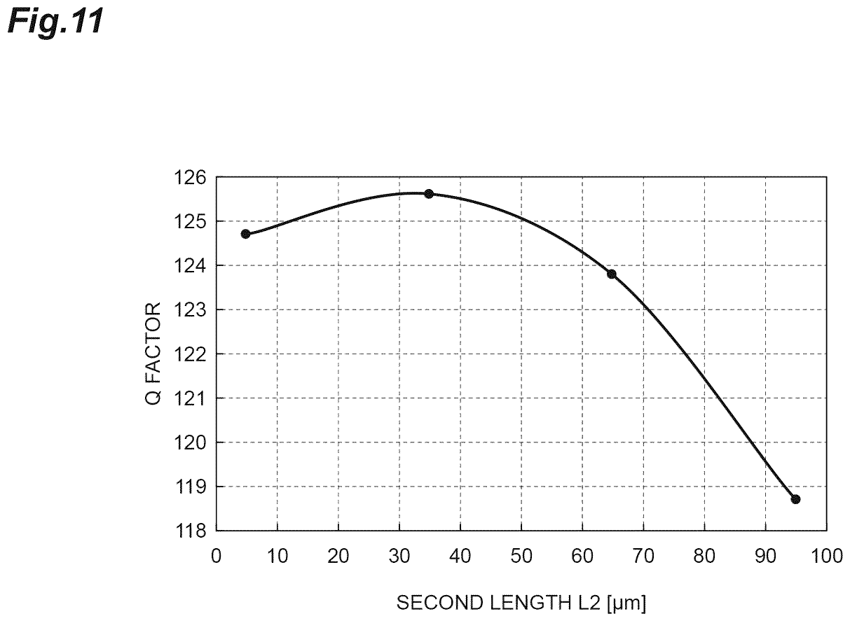

FIG. 11 is a graph showing a relationship between the second length L2 of each of the first conductor 72 and the second conductor 73 and the Q factor. In FIG. 11, the horizontal axis represents the second length L2 [μm] of each of the first conductor 72 and the second conductor 73, and the vertical axis represents the Q factor. FIG. 11 shows a result at a frequency of 13 GHz.

As shown in FIG. 11, in the electronic component 1B, when a first value on the horizontal axis is denoted by X1, a second value on the horizontal axis is by X2, a first Q factor on the vertical axis at the first value X1 is by Y1, and a second Q factor on the vertical axis at the second value X2 is by Y2,
the slope of the graph of

(Y2−Y1)/(X2−X1)
is negative. That is, in the electronic component 1B, the first conductor 72 and the second conductor 73 are configured such that the slope of the graph is negative in the above relationship.

In the example shown in FIG. 11, in the electronic component 1B, for example, X1 can be 35 μm, X2 can be 65 μm, Y1 can be 125.6, and Y2 can be 123.8. In this case, the slope of the graph is negative. In the electronic component 1B, for example, X1 can be 65 μm, X2 can be 95 μm, Y1 can be 123.8, and Y2 can be 118.7. In the present embodiment, the Q factor is maximized when the second length L2 is 35 μm.

As described hereinabove, in the electronic component 1B according to the present embodiment, for the first conductor 72 and the second conductor 73, the first length L1 in the first direction D1 is longer than the second length L2 in the third direction D3 (L1>L2) when viewed from the second direction D2. Thereby, in the electronic component 1B, an opening formed by the first conductor 72, the second conductor 73, and the inductor conductor 74 can be enlarged while an increase in the dimension of the element body 2 in the third direction D3 is avoided. Therefore, in the electronic component 1B, inductance can be increased while downsizing is achieved. In this configuration, in the electronic component 1B, in a graph in which the horizontal axis represents the value of the second length L2 of each of the first conductor 72 and the second conductor 73 and the vertical axis represents the Q factor (quality factor), when a first Q factor on the vertical axis at a first value X1 is denoted by Y1 and a second Q factor on the vertical axis at a second value X2 is by Y2, the slope of the graph of (Y2−Y1)/(X2−X1) is negative. The electronic component 1B has such characteristics.

Hereinabove, embodiments of the present invention are described; however, the present invention is not necessarily limited to the above-described embodiments, and various changes can be made without departing from the gist thereof.

In the above first embodiment, a mode in which, for each of the first conductor 13 and the second conductor 14, the first length L1 in the first direction D1 is longer than the second length L2 in the third direction D3 (L1>L2) when viewed from the second direction D2 is described as an example. However, it is sufficient that, when viewed from the second direction D2, the first length L1 in the first direction D1 be longer than the second length L2 in the third direction D3 in at least one of the first conductor 13 and the second conductor 14. The same applies to the first conductor 43, the second conductor 44, the third conductor 45, and the fourth conductor 46 of the second embodiment and the first conductor 72 and the second conductor 73 of the third embodiment.

In the above first embodiment, a mode in which the first conductor 13 and the second conductor 14 each exhibit a shape in which a plurality of circles overlap and have recesses 13C and 14C is described as an example. However, the shapes of the first conductor 13 and the second conductor 14 are not limited thereto. Each of the first conductor 13 and the second conductor 14 may be, for example, in a rectangle shape, an elliptical shape, or the like. The same applies to the second embodiment and the third embodiment.

In the above embodiments, the configuration of the terminal electrode (terminal conductor) is not limited.

In another aspect of the present invention, an electronic component includes: an element body formed by stacking a plurality of insulator layers; and a resonator placed in the element body; in the electronic component, the resonator includes two conductors extending in the stacking direction of the plurality of insulator layers and a connection conductor connecting the two conductors, in at least one conductor of the two conductors, when the conductor is viewed from the stacking direction, a first length in a direction orthogonal to the facing direction of the two conductors is longer than a second length in the facing direction, and in a graph in which the horizontal axis represents the width dimension in the facing direction of the two conductors and the vertical axis represents the Q factor, when a first value on the horizontal axis is denoted by X1, a second value on the horizontal axis is by X2, a first Q factor on the vertical axis at the first value X1 is by Y1, and a second Q factor on the vertical axis at the second value X2 is by Y2, the value of (Y2−Y1)/(X2−X1) is negative.

In the above electronic component, in at least one conductor of the two conductors, when the conductor is viewed from the stacking direction, a first length in a direction orthogonal to the facing direction of the two conductors is longer than a second length in the facing direction. Thereby, in the electronic component, an opening formed by the two conductors and the connection conductor can be enlarged while an increase in the dimension of the element body in the facing direction is avoided. Therefore, in the electronic component, inductance can be increased while downsizing is achieved. In this configuration, in the electronic component, in a graph in which the horizontal axis represents the value of the width dimension in the facing direction of the two conductors and the vertical axis represents the Q factor (quality factor), when a first Q factor on the vertical axis at a first value X1 is denoted by Y1 and a second Q factor on the vertical axis at a second value X2 is by Y2, the slope of the graph of (Y2−Y1)/(X2−X1) is negative. In the electronic component, the Q factor can be improved by having such characteristics.

What is claimed is:

1. An electronic component comprising:
an element body formed by stacking a plurality of insulator layers; and
a resonator placed in the element body,
wherein the resonator includes two conductors extending in a stacking direction of the plurality of insulator layers and a connection conductor connecting the two conductors,
in at least one conductor of the two conductors, when the conductor is viewed from the stacking direction, a first length in a direction orthogonal to a facing direction of the two conductors is longer than a second length in the facing direction, and
in a graph in which a horizontal axis represents a value of the second length of the conductor and a vertical axis represents a Q factor, when a first value on the horizontal axis is denoted by X1, a second value on the horizontal axis is by X2, a first Q factor on the vertical axis at the first value X1 is by Y1, and a second Q factor on the vertical axis at the second value X2 is by Y2, a slope of the graph of (Y2−Y1)/(X2−X1) is negative.

2. The electronic component according to claim 1, wherein the second length of the conductor is 125 μm or less.

3. The electronic component according to claim 1,
wherein a plurality of recesses are provided on a side surface of the conductor, and
the plurality of recesses are arranged facing in the facing direction and extend in the stacking direction.

4. The electronic component according to claim 1,
wherein, for each of the two conductors, the first length is longer than the second length, and
each of the first length and the second length is the same between the two conductors.

5. The electronic component according to claim 1, wherein, as viewed from the stacking direction, the direction orthogonal to the facing direction of the two conductors is along a longitudinal direction of the element body.

6. The electronic component according to claim 1, wherein the resonator includes a plurality of sets each consisting of the two conductors and the connection conductor.

7. An electronic component comprising:
an element body formed by stacking a plurality of insulator layers; and
a resonator placed in the element body,
wherein the resonator includes two conductors extending in a stacking direction of the plurality of insulator layers and a connection conductor connecting the two conductors,
in at least one conductor of the two conductors, when the conductor is viewed from the stacking direction, a first length in a direction orthogonal to a facing direction of the two conductors is longer than a second length in the facing direction, and
in a graph in which a horizontal axis represents a width dimension in the facing direction of the two conductors and a vertical axis represents a Q factor, when a first value on the horizontal axis is denoted by X1, a second value on the horizontal axis is by X2, a first Q factor on the vertical axis at the first value X1 is by Y1, and a second Q factor on the vertical axis at the second value X2 is by Y2, a value of (Y2−Y1)/(X2−X1) is negative.
